(19) United States
(12) Patent Application Publication
(10) Pub. No.: US 2014/0240369 A1
(43) Pub. Date: Aug. 28, 2014

(54) SEMICONDUCTOR DEVICE AND DISPLAY APPARATUS

(71) Applicant: FITIPOWER INTEGRATED TECHNOLOGY, INC., Hsinchu City (TW)

(72) Inventor: WEN-SHIAN SHIE, Hsinchu (TW)

(73) Assignee: FITIPOWER INTEGRATED TECHNOLOGY, INC., Hsinchu City (TW)

(21) Appl. No.: 14/080,820

(22) Filed: Nov. 15, 2013

(30) Foreign Application Priority Data
Feb. 27, 2013 (TW) 102106866

(51) Int. Cl. H01L 27/02; G09G 5/18

(52) U.S. Cl. CPC H01L 27/0251; G09G 5/18
USPC 345/690; 257/355

(57) ABSTRACT

A semiconductor device includes a p-substrate, a digital circuit unit, and an analogy circuit unit. The digital circuit unit includes a deep n-well, a first p-type semiconductor element, a first n-type semiconductor element, and a p-well. The deep n-well is formed on the p-substrate, the first p-type semiconductor element and the p-well are formed on the deep n-well, and the first n-type semiconductor element formed on the p-well. The analogy circuit unit includes a second p-type semiconductor element, a second n-type semiconductor element, and an n-well. The second n-type semiconductor element and the n-well are formed on the p-substrate, and the second p-type semiconductor element formed on the n-well.

### BACKGROUND

1. Technical Field

The present disclosure relates to a semiconductor device and a display apparatus using the same.

2. Description of Related Art

Semiconductor devices, such as semiconductor chips, usually have a substrate, a digital circuit unit and an analog circuit unit formed on the substrate. Generally, a withstand voltage of semiconductor elements of the digital circuit unit may be 3.3 volts, and a withstand voltage of semiconductor elements of the analog circuit unit may be 10 volts. Sometimes, the substrate needs to connect a negative reference voltage to make the analog circuit unit output positive voltages and negative voltages. However, when the substrate connects the negative reference voltage, the semiconductor elements of the digital circuit unit may suffer a voltage greater than 3.3 volts. Accordingly, the semiconductor elements of the digital circuit unit may be damaged.

What is needed, therefore, is to provide a means that solves the problem discussed above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of a display apparatus including a semiconductor device according to an embodiment of the present disclosure.

FIG. 2 is a cross-section view of the semiconductor device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

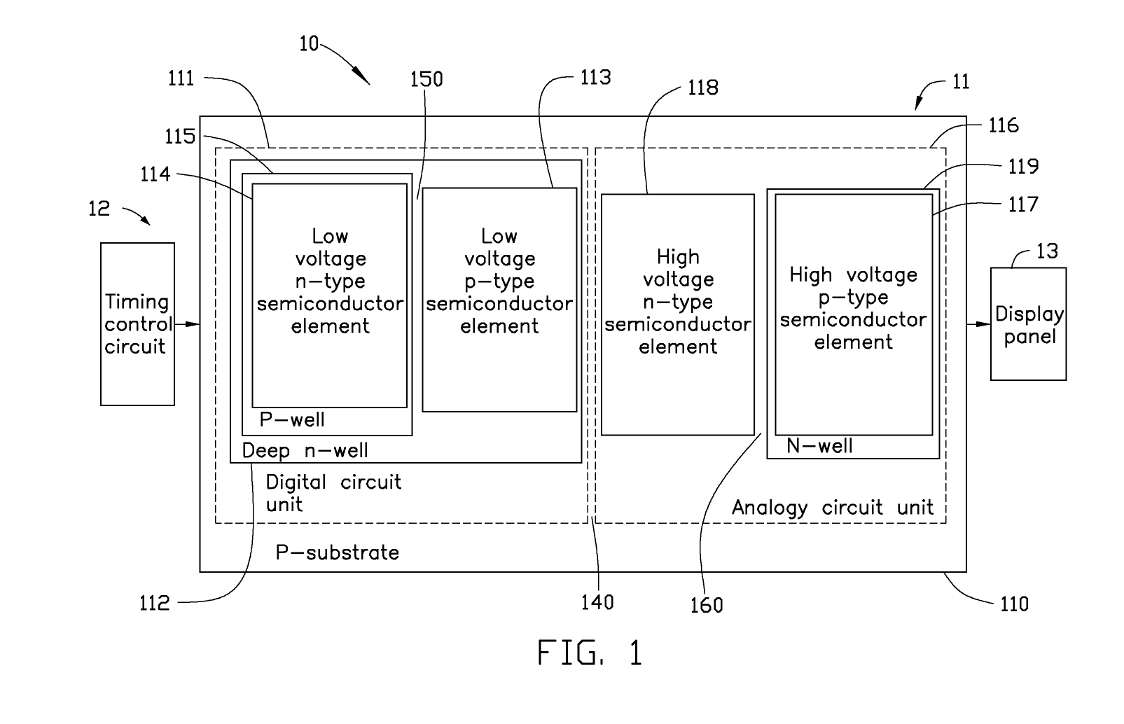

FIG. 1 shows a display apparatus 10 according to an embodiment of the present disclosure. The display apparatus 10 includes a timing control circuit 12, a display panel 13, and a semiconductor device 11 connected between the timing control circuit 12 and the display panel 13. The display panel 13 may be a liquid crystal display panel. The semiconductor device 11 may be a source driving circuit, and the semiconductor device 11 is configured to receive digital image signals and provide analogy gray voltage signals to the display panel 13.

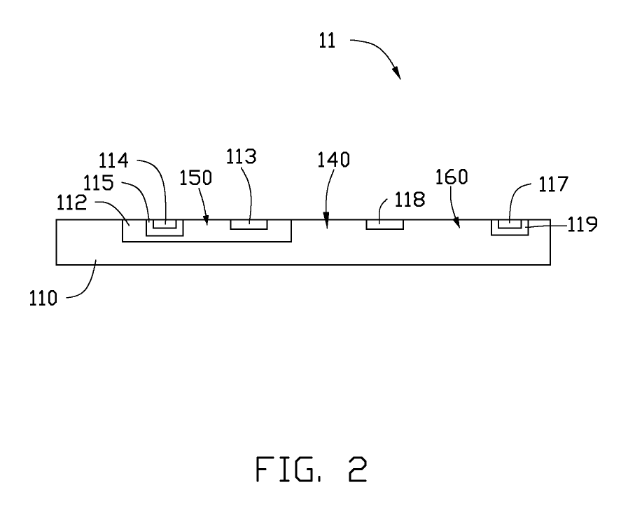

FIG. 2 shows a cross-section view of the semiconductor device 11. The semiconductor device 11 includes a p-substrate 110, a digital circuit unit 111, and an analogy circuit unit 116. The p-substrate 110 is configured to receive a reference voltage which has the lowest voltage value of the semiconductor device 11. The digital circuit unit 111 and the analogy circuit unit 116 are formed on the same p-substrate 110 and spaced from each other. In particular, a first isolation rule 140 is located between the digital circuit unit 111 and the analogy circuit unit 116 to reduce interference between the digital circuit unit 111 and the analogy circuit unit 116.

The digital circuit unit 111 is configured to receive first digital image signals of the timing control circuit 12 and output second digital signals, and the digital circuit unit 111 includes a deep n-well 112, a low voltage p-type semiconductor element 113, a low voltage n-type semiconductor element 114, and an p-well 115. The deep n-well 112 is formed on the p-substrate 110. The low voltage p-type semiconductor element 113 and the p-well 115 are formed on the deep n-well 112. The low voltage n-type semiconductor element 114 is formed on the p-well 115. A second isolation rule 150 is located between the low voltage p-type semiconductor element 113 and the low voltage n-type semiconductor element 114.

The analogy circuit unit 116 is configured to receive the second digital image signals and output analogy gray voltage signals to the display panel 13, and the analogy circuit unit 116 includes a high voltage p-type semiconductor element 117, a high voltage n-type semiconductor element 118, and an n-well 119. The high voltage n-type semiconductor element 118 and the n-well 119 are formed on the p-substrate 110, and the high voltage p-type semiconductor element 117 is formed on the n-well 119. A third isolation rule 160 is located between the high voltage p-type semiconductor element 117 and the high voltage n-type semiconductor element 118.

The analogy gray voltage signals of the analogy circuit unit 116 include positive gray voltage signals and negative gray voltage signals. A maximum difference value between the positive gray voltage signals and the negative gray voltage signals is defined as “A”. In one embodiment, “A” is greater than or equal to 12 volts and less than 20 volts, such as 13.5 volts, 16.5 volts or 18 volts. In other embodiment, “A” can be 6 volts.

In the embodiment, the analogy circuit unit 116 may be used in three display apparatuses with different types. In a first type of a display apparatus, the p-substrate receives a first reference voltage (such as 0 volt), the positive voltage signals output by the analogy circuit unit 116 are in the range from 0 volt to “A” volts, and the negative voltage signals output by the analogy circuit unit 116 are also in the range from 0 volt to A volts. In a second type of a display apparatus, the p-substrate receives a second reference voltage (such as 0 volt), the positive voltage signals output by the analogy circuit unit 116 are in the range from “A/2” volts to “A” volts, and the negative voltage signals output by the analogy circuit unit 116 are in the range from “A/2” volts to “A” volts. In a third type of a display apparatus, the p-substrate receives a third reference voltage (such as—A/2 volt), the positive voltage signals output by the analogy circuit unit 116 are in the range from“A/2” volts to “A” volts, and the negative voltage signals output by the analogy circuit unit 116 are also in the range from“A/2” volts to “A” volts.

The digital image signals output by the digital circuit unit 111 include a high level voltage corresponding to logic “1” and a low level voltage corresponding to logic “0”, and a difference value between the high level voltage and the low level voltage is defined as “B”. It can be understood, “B” is usually less than 4 volts. In one embodiment, “B” is 3.3 volts. In other embodiment, “B” can be 1.2 volts or 1.8 volts.

In the embodiment, the lower voltage p-type semiconductor element 113 is defined as a p-type semiconductor element with a withstand voltage which is in the range from “B” volts to 4 volts. The lower voltage n-type semiconductor element 114 is defined as an n-type semiconductor element with a withstand voltage which is in the range from “B” volts to 4 volts. The high voltage p-type semiconductor element 117 is defined as a p-type semiconductor element with a withstand voltage greater than or equal to “A” volts. The high voltage n-type semiconductor element 118 is defined as an n-type semiconductor element with a withstand voltage greater than or equal to “A” volts. It can be understood, “A” is usually less than or equal to 20 volts, accordingly, the withstand voltage of each of the high voltage p-type semiconductor element 117 and the high voltage n-type semiconductor element 118 can be in the range from “A” volts to 20 volts It can be understood, the p-type semiconductor element may be a PMOS, and the p-type semiconductor element may be an NMOS.

Because the low voltage n-type semiconductor element 114 is formed on the deep n-well 112 via the p-well 115, the reference voltage of the p-substrate is hard to influence the low voltage n-type semiconductor element 114. Accordingly, the semiconductor elements of the digital circuit unit can avoid to be damaged.

It is to be understood that the described embodiments are intended to illustrate rather than limit the disclosure. Any elements described in accordance with any embodiments is understood that they can be used in addition or substituted in other embodiments. Embodiments can also be used together. Variations may be made to the embodiments without departing from the spirit of the disclosure. The disclosure illustrates but does not restrict the scope of the disclosure.

What is claimed is:

1. A semiconductor device, comprising:
a p-substrate,
a digital circuit unit receiving first digital image signals and outputting second digital image signals, the digital circuit unit comprising a deep n-well, a first p-type semiconductor element, a first n-type semiconductor element, and a p-well, the deep n-well formed on the p-substrate, the first p-type semiconductor element and the p-well formed on the deep n-well, and the first n-type semiconductor element formed on the p-well; and
an analogy circuit unit receiving the second digital image signals and outputting analogy image signals, the analogy circuit unit comprising a second p-type semiconductor element, a second n-type semiconductor element, and an n-well, the second n-type semiconductor element and the n-well formed on the p-substrate, and the second p-type semiconductor element formed on the n-well.

2. The semiconductor device of claim 1, wherein the analogy image signals of the analogy circuit comprise positive gray voltage signals and negative gray voltage signals, a maximum difference value between the positive gray voltage signal and the negative gray voltage signal is defined as “A”, and a withstand voltage of each of the second p-type semiconductor element and the second n-type semiconductor element is greater than or equal to “A” volts.

3. The semiconductor device of claim 2, wherein the maximum difference value “A” is selected from the group consisting of 13.5 volts, 6 volts, 16.5 volts, and 18 volts.

4. The semiconductor device of claim 2, wherein the positive voltage signals output by the analogy circuit unit are in the range from 0 volt to “A” volts, and the negative voltage signals output by the analogy circuit unit are also in the range from 0 volt to A volts.

5. The semiconductor device of claim 2, wherein the positive voltage signals output by the analogy circuit unit are in the range from “A/2” volts to “A” volts, and the negative voltage signals output by the analogy circuit unit are in the range from “A/2” volts to “A” volts.

6. The semiconductor device of claim 2, wherein the positive voltage signals output by the analogy circuit unit are in the range from“A/2” volts to “A” volts, and the negative voltage signals output by the analogy circuit unit are also in the range from“A/2” volts to “A” volts.

7. The semiconductor device of claim 2, wherein the digital image signals output by the digital circuit unit comprises a high level voltage corresponding to logic “1” and a low level voltage corresponding to logic “0”, a difference value between the high level voltage and the low level voltage is defined as “B”, a withstand voltage of each of the first p-type semiconductor element and the first n-type semiconductor element is in the range from B to 4 volts.

8. The semiconductor device of claim 7, wherein the maximum difference value “B” is selected from the group consisting of 1.2 volts, 1.8 volts, and 3.3 volts.

9. The semiconductor device of claim 1, wherein each of the first and the second p-type semiconductor elements is a PMOS, and each of the first and the second p-type semiconductor element is an NMOS.

10. The semiconductor device of claim 1, a first isolation rule is located between the digital circuit unit and the analogy circuit unit, a second isolation rule is located between the first p-type semiconductor element and the first n-type semiconductor element, and a third isolation rule is located between the second p-type semiconductor element and the second n-type semiconductor element.

11. A display apparatus, comprising:
a timing control circuit;
a display panel; and
a source driving circuit connected between the timing control circuit and the display panel, the source driving circuit receiving first digital image signals from the timing control circuit and outputting analogy gray voltage signals to the display panel, the source driving circuit comprising
a p-substrate,
a digital circuit unit receiving the first digital image signals and outputting second digital image signals, the digital circuit unit comprising a deep n-well, a first p-type semiconductor element, a first n-type semiconductor element, and a p-well, the deep n-well formed on the p-substrate, the first p-type semiconductor element and the p-well formed on the deep n-well, and the first n-type semiconductor element formed on the p-well; and
an analogy circuit unit receiving the second digital image signals and outputting analogy image signals, the analogy circuit unit comprising a second p-type semiconductor element, a second n-type semiconductor element, and an n-well, the second n-type semiconductor element and the n-well formed on the p-substrate, and the second p-type semiconductor element formed on the n-well.

12. The display apparatus of claim 11, wherein the analogy image signals of the analogy circuit comprise positive gray voltage signals and negative gray voltage signals, a maximum difference value between the positive gray voltage signal and the negative gray voltage signal is defined as “A”, and a withstand voltage of each of the second p-type semiconductor element and the second n-type semiconductor element is greater than or equal to “A” volts.

13. The display apparatus of claim 12, wherein the maximum difference value “A” is selected from the group consisting of 13.5 volts, 6 volts, 16.5 volts, and 18 volts.

14. The display apparatus of claim 12, wherein the positive voltage signals output by the analogy circuit unit are in the range from 0 volt to “A” volts, and the negative voltage signals output by the analogy circuit unit are also in the range from 0 volt to A volts.

15. The display apparatus of claim 12, wherein the positive voltage signals output by the analogy circuit unit are in the range from “A/2” volts to “A” volts, and the negative voltage signals output by the analogy circuit unit are in the range from “A/2” volts to “A” volts.

16. The display apparatus of claim 12, wherein the positive voltage signals output by the analogy circuit unit are in the range from“A/2” volts to “A” volts, and the negative voltage signals output by the analogy circuit unit are also in the range from“A/2” volts to “A” volts.

17. The display apparatus of claim 12, wherein the digital image signals output by the digital circuit unit comprises a high level voltage corresponding to logic “1” and a low level voltage corresponding to logic “0”, a difference value between the high level voltage and the low level voltage is defined as “B”, a withstand voltage of each of the first p-type semiconductor element and the first n-type semiconductor element is in the range from B to 4 volts.

18. The display apparatus of claim 17, wherein the maximum difference value “B” is selected from the group consisting of 1.2 volts, 1.8 volts, and 3.3 volts.

19. The display apparatus of claim 11, wherein each of the first and the second p-type semiconductor elements is a PMOS, and each of the first and the second p-type semiconductor element is an NMOS.

20. The display apparatus of claim 11, a first isolation rule is located between the digital circuit unit and the analogy circuit unit, a second isolation rule is located between the first p-type semiconductor element and the first n-type semiconductor element, and a third isolation rule is located between the second p-type semiconductor element and the second n-type semiconductor element.
